(19) United States
(12) Patent Application Publication
(10) Pub. No.: US 2017/0085270 A1
(43) Pub. Date: Mar. 23, 2017

(54) SEMICONDUCTOR DEVICE, RADIO COMMUNICATION APPARATUS, AND CONTROL METHOD FOR SEMICONDUCTOR DEVICE

(71) Applicant: Renesas Electronics Corporation, Tokyo (JP)

(72) Inventors: Hidehiko SUZUKI, Tokyo (JP); Naoki KOIZUMI, Tokyo (JP); Hisaya ISHIHARA, Tokyo (JP); Kazuhiro KIJIMA, Tokyo (JP)

(21) Appl. No.: 15/224,368

(22) Filed: Jul. 29, 2016

(30) Foreign Application Priority Data
Sep. 18, 2015 (JP) 2015-185071

(51) Int. Cl. H03L 1/02; H03L 7/089; H03B 5/12; H03B 5/32

(52) U.S. Cl. CPC H03L 1/026; H03B 5/32; H03L 7/0891; H03B 5/1212; H03B 2200/004

(57) ABSTRACT

An object is to avoid a deadlock in a PLL. A PLL synthesizer includes a PLL circuit that includes a voltage control oscillation circuit configured to control an oscillation frequency according to a control voltage, an oscillation frequency storage unit configured to previously store the oscillation frequency at a first temperature, a control voltage setting unit configured to set a control voltage based on a difference between the oscillation frequency at a second temperature and the stored oscillation frequency, and a calibration processing unit configured to calibrate the voltage control oscillation circuit in a state in which the control voltage is set so that the oscillation frequency will become a predetermined frequency.

### CROSS-REFERENCE TO RELATED APPLICATIONS

This application is based upon and claims the benefit of priority from Japanese patent application No. 2015-185071, filed on Sep. 18, 2015, the disclosure of which is incorporated herein in its entirety by reference.

### BACKGROUND

The present invention relates to a semiconductor device, a radio communication apparatus, and a control method for the semiconductor device, and to, for example, a semiconductor device and a radio communication apparatus that each include a PLL circuit, and a control method for the semiconductor device.

A Phase Locked Loop (PLL) circuit that is used for demodulating and modulating radio signals is mounted on a radio communication apparatus. For example, a TV tuner uses a PLL circuit that supports a plurality of CHs (channels) in order to select a CH for reception from among the plurality of CHs. The PLL circuit that supports a plurality of frequencies includes a Voltage Controlled Oscillator (VCO) having a wide frequency range. A circuit disclosed in Japanese Unexamined Patent Application Publication No. 2004-7433 is well known as such a PLL circuit.

### SUMMARY

It is known that an oscillation frequency of a VCO is fluctuated according to a temperature (which is referred to as a temperature drift). A deadlock in a PLL caused by a temperature drift in a VCO will become a problem when an operation of a radio communication apparatus operating in a wideband is to be guaranteed in an environment where an ambient temperature of the radio communication apparatus is greatly fluctuated. A deadlock indicates a state in which a PLL is unlocked by a fluctuation in an oscillation frequency of a VCO, and then the PLL cannot be locked again.

In some radio communication apparatuses, when a deadlock occurs in a PLL, software or hardware is reset, and then the PLL is locked again, which is not considered as a problem. However, resetting the radio communication apparatus such as a TV tuner is a last option, and the apparatus is configured in such a way that a deadlock will not occur in a guaranteed temperature environment. It is therefore necessary to avoid a deadlock in a PLL that operates in a wideband while performing a continuous operation in the radio communication apparatus such as a TV tuner.

Thus, one of objects of an aspect is to avoid a deadlock in a PLL. Other problems of the related art and new features of the present invention will become apparent from the following descriptions of the specification and attached drawings.

An aspect is a semiconductor device used for a radio communication apparatus or the like includes a PLL circuit, an oscillation frequency storage unit, a control voltage setting unit, and a calibration processing unit. The PLL circuit includes a voltage control oscillation circuit is configured to control an oscillation frequency according to a control voltage. The oscillation frequency storage unit is configured to previously store the oscillation frequency at a first temperature. The control voltage setting unit is configured to set the control voltage based on a difference between the oscillation frequency at a second temperature and the stored oscillation frequency. The calibration processing unit is configured to calibrate the voltage control oscillation circuit in a state in which the control voltage is set so that the oscillation frequency will become a predetermined frequency.

According to the above aspect, a deadlock in a PLL can be avoided.

### BRIEF DESCRIPTION OF THE DRAWINGS

The above and other aspects, advantages and features will be more apparent from the following description of certain embodiments taken in conjunction with the accompanying drawings, in which:

FIG. 1 is a configuration diagram showing a configuration example of a radio communication apparatus according to a first embodiment;

FIG. 2 is a configuration diagram showing an outline of a PLL synthesizer according to the first embodiment;

FIG. 3 is a configuration diagram showing a configuration example of a PLL synthesizer according to a basic example 1;

FIG. 4 is a configuration diagram showing a configuration example of a VCO according to the basic example 1;

FIG. 5 is a graph showing a temperature drift example according to the basic example 1;

FIG. 6 is a graph showing a relationship between CHs and capacitor banks in a PLL synthesizer according to the basic example 1;

FIG. 7 is a graph showing a relationship between the capacitor banks and a VCO gain in the PLL synthesizer according to the basic example 1;

FIG. 8 is a configuration diagram showing a configuration example of a PLL synthesizer according to a basic example 2;

FIG. 9 is a configuration diagram showing a configuration example of a VCO according to the basic example 2;

FIG. 10 is a drawing for explaining a calibration operation of the VCO according to the basic example 2;

FIG. 11 is a drawing for explaining the calibration operation of the VCO according to the basic example 2;

FIG. 12 is a graph showing a change in a VCO control voltage when a temperature changes according to the basic example 1;

FIG. 13 is a graph showing a change in a VCO control voltage when a temperature changes according to the basic example 2;

FIG. 14 is a graph showing a relationship between the VCO control voltage and a VCO oscillation frequency according to the basic example 2;

FIG. 15 is a graph showing a relationship between an ambient temperature and the VCO control voltage according to the basic example 2;

FIG. 16 is a graph showing a relationship between CHs and an amount of lock voltage fluctuations according to the basic example 2;

FIG. 17 is a configuration diagram showing a configuration example of the PLL synthesizer according to the first embodiment;

FIG. 18 is a configuration diagram showing a configuration example of a bias circuit according to the first embodiment;

FIG. 19 is a drawing showing a specific example of a temperature table according to the first embodiment;

FIG. 20 is a flowchart showing an operation example of the PLL synthesizer according to the first embodiment;

FIG. 21 is a graph showing a temperature drift example according to the first embodiment;

FIG. 22 is a graph showing a relationship between a VCO control voltage and a VCO oscillation frequency according to the first embodiment;

FIG. 23 is a graph showing a relationship between an ambient temperature and the VCO control voltage according to the first embodiment; and

FIG. 24 is a graph showing a relationship between CHs and an amount of lock voltage fluctuations according to the first embodiment.

### DETAILED DESCRIPTION

The following descriptions and drawings are omitted and simplified as appropriate for clarity of the description. Further, the elements illustrated in the drawings as functional blocks for performing various processes can be implemented hardware-wise by a CPU, a memory, and other circuits, and software-wise by a program loaded onto a memory or the like. Accordingly, it is to be understood by those skilled in the art that these functional blocks can be implemented in various forms including, but not limited to, being implemented by hardware alone, software alone, or a combination of hardware and software. Note that in the drawings, the same elements are denoted by the same reference signs, and repeated descriptions will be omitted as needed.

### First Embodiment

Hereinafter, a first embodiment will be described with reference to the drawings.

### <Configuration of Radio Communication Apparatus>

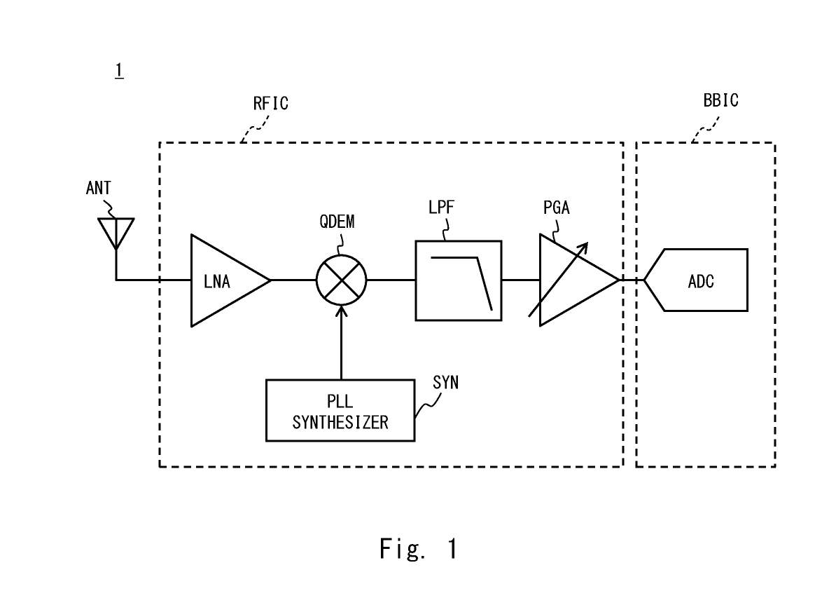

FIG. 1 shows a configuration of a radio communication apparatus according to this embodiment. Although a radio communication apparatus 1 according to this embodiment is, for example, a TV tuner and is a reception apparatus that receives radio signals in a plurality of CHs, it may be another reception apparatus or a transmission apparatus. In the case of the reception apparatus, the reception apparatus processes reception signals based on an oscillation frequency generated by a PLL synthesizer according to this embodiment, while in the case of the transmission apparatus, the transmission apparatus processes transmission signals based on the oscillation frequency generated by the PLL synthesizer according to this embodiment.

As shown in FIG. 1, the radio communication apparatus 1 includes an antenna ANT, a radio signal processing device RFIC, and a baseband processing device BBIC. The antenna ANT receives radio signals in a plurality of CHs such as digital TV broadcasting. For example, although both of the radio signal processing device RFIC and the baseband processing device BBIC are one-chip semiconductor devices, the radio signal processing device RFIC and the baseband processing device BBIC may be included in one semiconductor device.

The radio signal processing device RFIC is a semiconductor device that processes radio signals (RF signals) received by the antenna ANT. The radio signal processing device RFIC converts signals in a selected CH from among received radio signals in a wideband into baseband signals that can be processed by the baseband processing device BBIC and outputs the generated baseband signals. The radio signal processing device RFIC includes a low-noise amplifier LNA, a PLL synthesizer SYN, a quadrature demodulator QDEM, a low-pass filter LPF, and a programmable gain amplifier PGA.

The low-noise amplifier LNA amplifies the radio signals received through the antenna ANT with low noise and outputs the amplified radio signals. The PLL synthesizer SYN is a PLL oscillator according to this embodiment and generates an oscillation signal having a frequency that is used to demodulate the radio signals. The baseband processing device BBIC sets a CH to the PLL synthesizer SYN, and the PLL synthesizer SYN generates an oscillation signal having a frequency according to the set CH.

The quadrature demodulator QDEM uses the oscillation signal generated by the PLL synthesizer SYN to quadrature-demodulate the signal amplified by the low-noise amplifier LNA and generate a baseband signal in the selected CH, and then outputs the baseband signal. The low-pass filter LPF removes a high-frequency component from the baseband signal generated by the quadrature demodulator QDEM. The programmable gain amplifier PGA amplifies the baseband signal, noise of which has been removed by the low-pass filter LPF. The baseband processing device BBIC sets a gain to the programmable gain amplifier PGA, and the programmable gain amplifier PGA outputs the baseband signal amplified by the set gain to the baseband processing device BBIC.

The baseband processing device BBIC is a semiconductor device that processes the baseband signal generated by the radio signal processing device RFIC. The baseband processing device BBIC decodes the input baseband signal and outputs decoded data. For example, the baseband processing device BBIC includes an AD converter ADC that converts input analog signals into digital signals, a decoder (not shown) that decodes digital signals into video data for a TV, and a control circuit (not shown) that controls an operation of the radio signal processing device RFIC.

### <Outline of PLL Synthesizer According to First Embodiment>

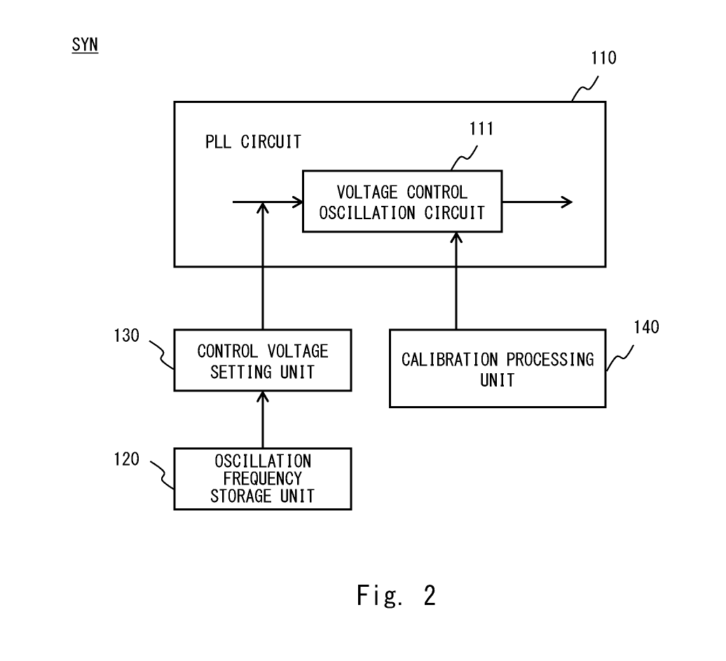

FIG. 2 shows an outline configuration of the PLL synthesizer SYN according to this embodiment. As shown in FIG. 2, the PLL synthesizer SYN (the semiconductor device) according to this embodiment includes a PLL circuit 110, an oscillation frequency storage unit 120, a control voltage setting unit 130, and a calibration processing unit 140.

The PLL circuit 110 includes a voltage control oscillation circuit 111 that controls an oscillation frequency according to a control voltage. The oscillation frequency storage unit 120 previously stores an oscillation frequency of the voltage control oscillation circuit 111 at a first temperature. The control voltage setting unit 130 sets a control voltage of the voltage control oscillation circuit 111 based on a difference between an oscillation frequency at a second temperature and the oscillation frequency stored in the oscillation frequency storage unit 120. The calibration processing unit 140 calibrates the voltage control oscillation circuit 111 in a state in which the control voltage is set by the control voltage setting unit 130 so that the oscillation frequency will become a predetermined frequency.

As described above, as the control voltage of the voltage control oscillation circuit used for the calibration is set based on the difference between the oscillation frequency at the first temperature (e.g., a normal temperature) and the oscillation frequency at the second temperature (e.g., a temperature during an operation), the control voltage can be set according to a temperature fluctuation, and thus a deadlock can be avoided

Firstly, basic examples 1 and 2 that show basics of the PLL synthesizer according to the first embodiment will be described, and then the PLL synthesizer according to the first embodiment will be described in detail in order to understand the first embodiment in more detail.

### <PLL Synthesizer According to Basic Example 1>

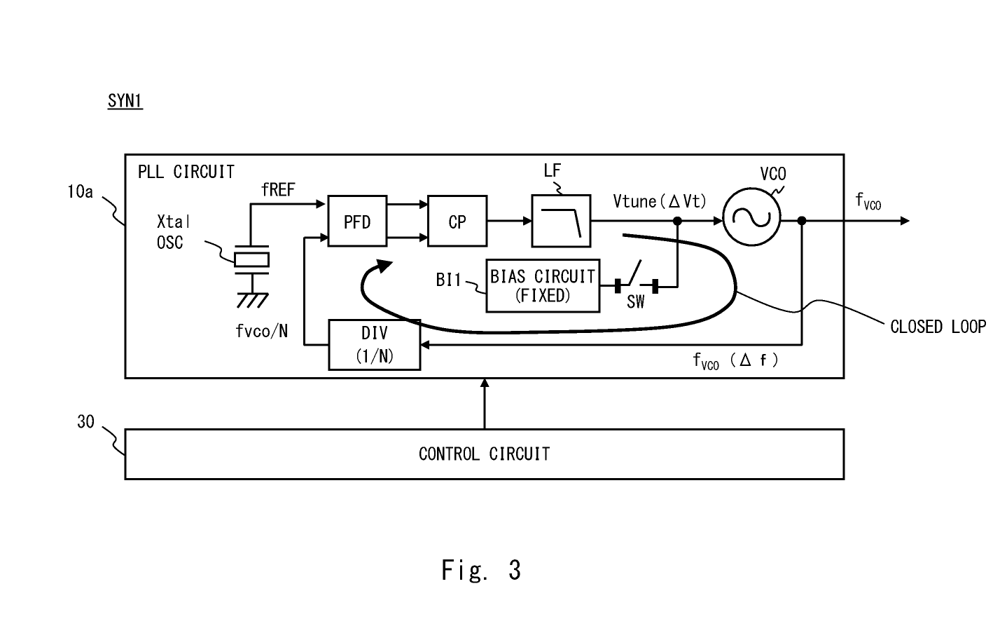

FIG. 3 shows a configuration of a PLL synthesizer SYN 1 according to the basic example 1. As shown in FIG. 3, the PLL synthesizer SYN 1 according to the basic example 1 includes a PLL circuit 10a and a control circuit 30. The control circuit 30 controls an operation of the PLL circuit 10a and is provided in the radio signal processing device RFIC or the baseband processing device BBIC.

The PLL circuit 10a according to the basic example 1 includes a crystal oscillator OSC (Xtal OSC), a phase frequency detector PFD, a charge pump CP, a loop filter LF, a voltage control oscillator VCO, a frequency divider DIV, and a bias circuit BI1. The crystal oscillator OSC (Xtal OSC) generates a reference frequency signal fREF having a predetermined frequency to be a reference. Note that the reference frequency signal or a reference frequency may be referred to as fREF. The phase frequency detector PFD compares the reference frequency signal fREF from the crystal oscillator OSC with a frequency-divided signal (fvco/N) from the frequency divider DIV and then generates a phase difference signal according to a phase difference between these signals. The charge pump CP generates a control signal according to the phase difference signal from the phase frequency detector PFD. The loop filter LF is, for example, a low-pass filter that removes a high-frequency component from the control signal generated by the charge pump CP.

The bias circuit BI1 is connected between the loop filter LF and the voltage control oscillator VCO with a switch SW interposed therebetween. The control circuit 30 controls the switch SW to be turned on or off. The bias circuit BI1 according to the basic example 1 is a DC voltage source circuit that supplies a fixed voltage. When the power is on, the switch SW is turned on, and a voltage from the bias circuit BI1 serves as an initial value for a VCO control voltage Vtune. After that, the switch SW is turned off, and a voltage of the control signal that has passed through the loop filter LF is supplied to the voltage control oscillator VCO as the VCO control voltage Vtune.

The voltage control oscillator VCO generates a VCO oscillation frequency signal fvco according to the input VCO control voltage Vtune and outputs the VCO oscillation frequency signal fvco. Note that the VCO oscillation frequency signal or the VCO oscillation frequency may be referred to as fvco. The control circuit 30 sets a capacitor bank to the voltage control oscillator VCO so that the voltage control oscillator VCO is oscillated at a frequency according to CH. The frequency divider DIV divides the VCO oscillation frequency signal fvco generated by the voltage control oscillator VCO by a predetermined frequency division ratio (1/N) in order to generate a frequency-divided signal. The frequency division ratio of the frequency divider DIV is set by the control circuit 30.

The phase frequency detector PFD, the charge pump CP, the loop filter LF, the voltage control oscillator VCO, and the frequency divider DIV constitute a closed loop that is locked and generates the VCO oscillation frequency signal. In the closed loop, when a frequency of a feedback signal (the frequency-divided signal) is lower than that of the reference frequency signal fREF, the VCO control voltage Vtune is increased so that the VCO oscillation frequency fvco will become high. Whereas when the frequency of the feedback signal (the frequency-divided signal) is higher than that of the reference frequency signal fREF, the VCO control voltage Vtune is reduced so that the VCO oscillation frequency fvco will become low. Then, an oscillation frequency signal having a frequency N times as great as that of the reference frequency signal can be obtained, in which N indicates the frequency division ratio.

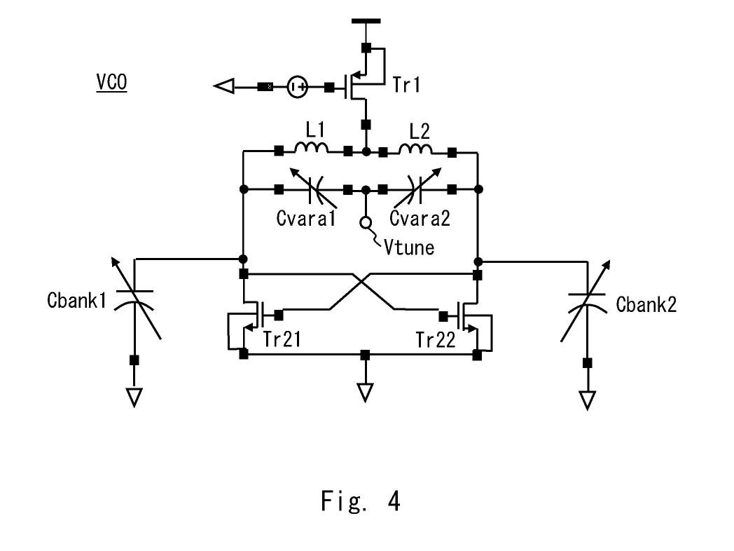

FIG. 4 shows a circuit configuration example of the voltage control oscillator VCO included in the PLL circuit 10a according to the basic example 1. The voltage control oscillator VCO is an example of an LC VCO and, as shown in FIG. 4, includes a Pch constant current source Tr1, inductors L1 and L2, varactor capacitors Cvara1 and Cvara2, oscillating transistors Tr21 and Tr22, and capacitor banks Cbank1 and Cbank1.

The inductors L1 and L2 are connected in series, and the varactor capacitors Cvara1 and Cvara2 are connected in series. The inductors L1 and L2 are connected in parallel to the varactor capacitors Cvara1 and Cvara2. A constant current is supplied from the Pch constant current source Tr1 to an intermediate node between the inductors L1 and L2. The VCO control voltage Vtune is supplied to an intermediate node between the varactor capacitors Cvara1 and Cvara2.

The capacitor bank Cbank1 and the oscillating transistor Tr21 are connected to a common node of the inductor L1 and the varactor capacitor Cvara1. The capacitor bank Cbank2 and the oscillating transistor Tr22 are connected to a common node of the inductor L2 and the varactor capacitor Cvara2.

The VCO oscillation frequency f(fvco) of the voltage control oscillator VCO is expressed by the (equation 1) below. Cvara is a capacitance of the varactor capacitors Cvara1 and Cvara2, and Cbank is a capacitance of the capacitor banks Cbank1 and Cbank2.

$$f = \frac{1}{2 \times π \times \sqrt{L \times ( {C}_{va r a} + {C}_{bank} )}} \qquad ( Equation 1 )$$

A VCO oscillation frequency f can be switched by switching the varactor capacitors Cvara1 and Cvara2 and the capacitor banks Cbank1 and Cbank2 using the (equation 1). Such a temperature drift in the LC VCO is generated due to a temperature fluctuation in the capacitances (Cvara and Cbank) shown in the (equation 1). That is, the VCO oscillation frequency fvco is fluctuated when the capacitances of the varactor capacitors Cvara1 and Cvara2 and the capacitor banks Cbank1 and Cbank2 of the voltage control oscillator VCO are fluctuated.

Although the PLL circuit has a loop so that the VCO oscillation frequency fvco is phase-synchronized with the reference frequency signal fREF, when a temperature drift in the voltage control oscillator VCO exceeds an operation range of the charge pump CP, a deadlock occurs in the PLL circuit. A relationship between the VCO oscillation frequency fluctuation Δf, Kvco (a VCO gain), and ΔVt (a fluctuation in the VCO control voltage Vtune) can be expressed by the following (equation 2). Roughly speaking, the VCO oscillation frequency fluctuation Δf, which is caused by a fluctuation in the temperature of the capacitances, is converted into ΔVt according to Kvco and fed back to the voltage control oscillator VCO.

$$Δ Vt [ V ] = \frac{Δ f [ MHz ]}{Kvco [ MHz \text{/} V ]} \qquad ( Equation 2 )$$

When the PLL circuit is used in an environment where an ambient temperature is greatly fluctuated, the VCO oscillation frequency fvco tends to be fluctuated to become high or low due to a temperature fluctuation after the VCO oscillation frequency fvco is converged. At this time, the PLL circuit discharges or charges a current of the charge pump CP in order to maintain the phase synchronization with the reference frequency signal and adjusts the VCO control voltage Vtune that is applied to the voltage control oscillator VCO. When there is a temperature fluctuation exceeding an operational limit of the charge pump CP, the voltage (the voltage applied to the VCO) of an output unit of the charge pump CP stays at a power supply or around GND, thereby disabling the operation of the charge pump CP and unlocking the PLL.

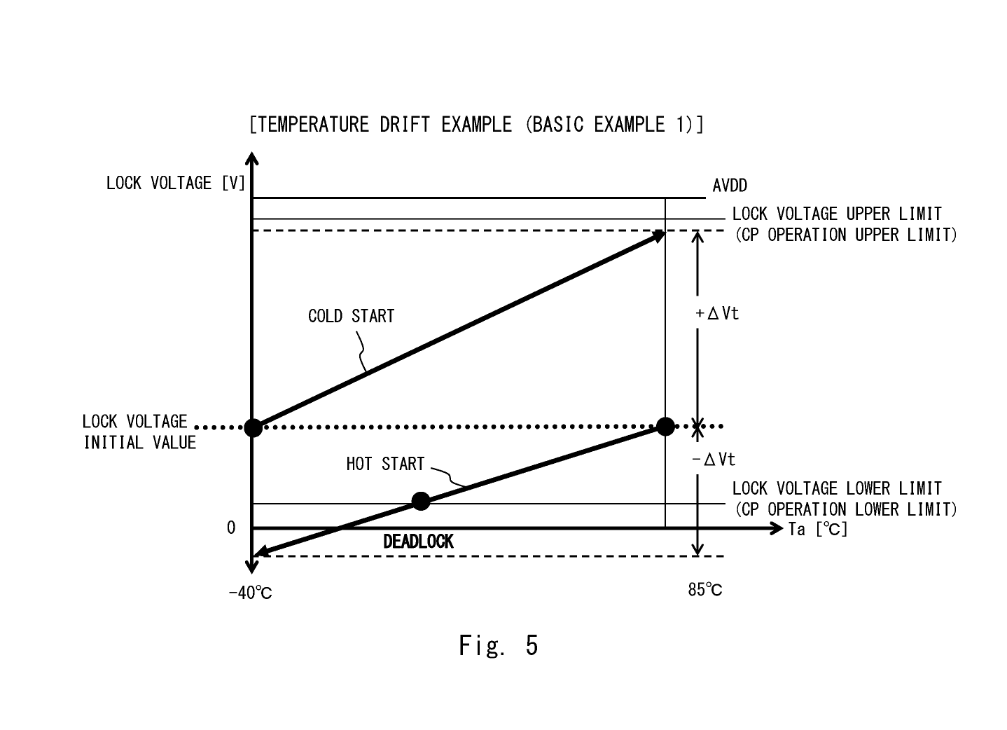

FIG. 5 shows a specific example of a deadlock in a PLL caused by a temperature drift in the voltage control oscillator VCO in the PLL circuit 10a according to the basic example 1. When the PLL circuit 10a according to the basic example 1 is cold-started, and an ambient temperature is fluctuated from −40 Celsius degrees to 85 Celsius degrees, a lock voltage (Vtune) increases from the initial value by ΔVt (the initial value+ΔVt) according to the temperature. At this time, as the increased lock voltage will not exceed an upper limit of the lock voltage, namely, an upper limit of an operation of the charge pump, a deadlock will not occur in the PLL.

On the other hand, when the PLL circuit 10a according to the basic example 1 is hot-started, and the ambient temperature is fluctuated from 85 Celsius degrees to −40 Celsius degrees, the lock voltage (Vtune) is reduced from the initial value by ΔVt (the initial value−ΔVt) according to the temperature. As the reduced lock voltage falls below a lower limit of the lock voltage, namely, a lower limit of an operation of the charge pump, a deadlock will occur in the PLL. In some radio communication apparatuses, when a deadlock occurs, the apparatus is reset, and then the PLL is locked again, which is not considered as a problem. However, as a TV tuner or the like cannot be reset, measures against a deadlock are required.

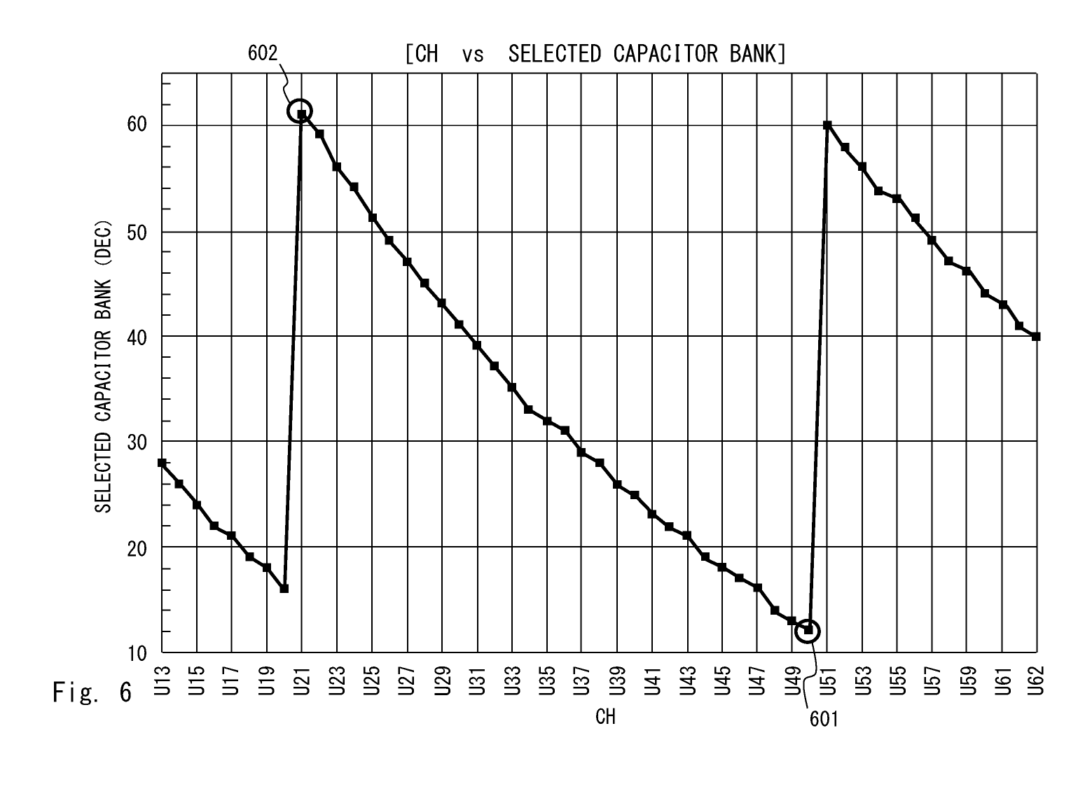

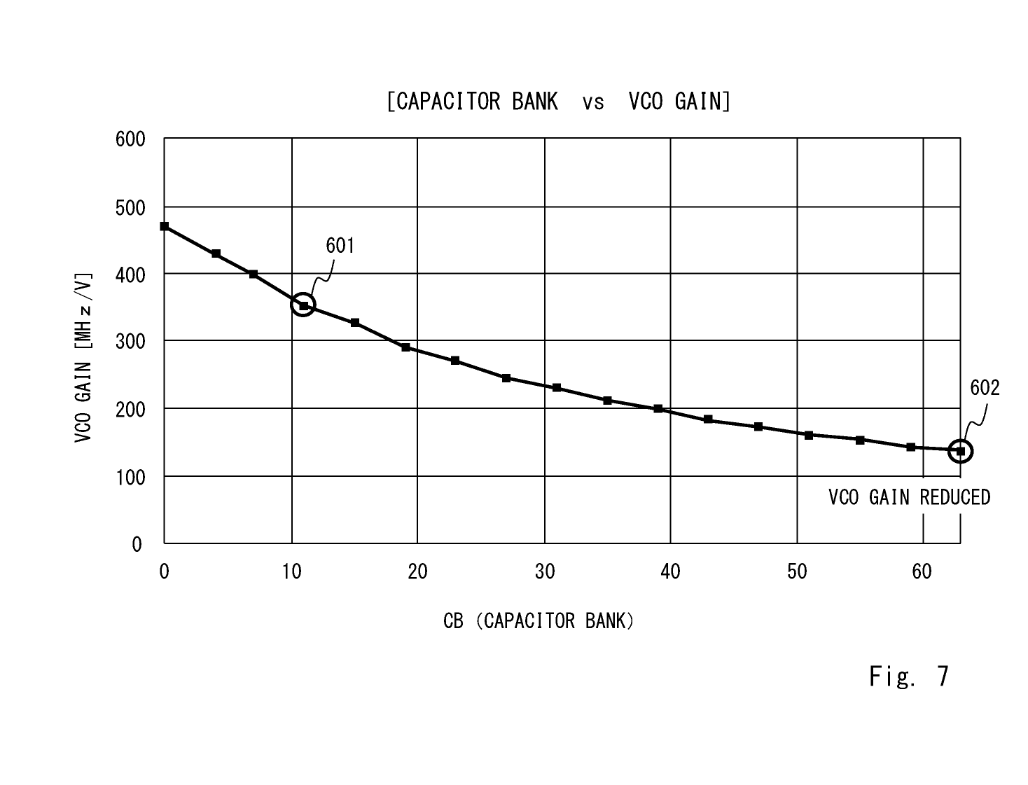

FIG. 6 is a graph showing a relationship between CHs and a capacitor bank in the PLL circuit according to the basic example 1, and FIG. 7 is a graph showing a relationship between capacitor banks and a VCO gain in the PLL circuit according to the basic example 1. FIGS. 6 and 7 are examples in which the PLL circuit according to the basic example 1 is applied to a TV tuner with CHs from CH13 (U13) to CH62 (U62) and a VCO oscillation frequency fvco within a range of about 1.8 GHz to 3.1 GHz.

As indicated by a sign 601 in FIGS. 6 and 7, when the CH is high, the capacitor bank is low, and the VCO gain (Kvco) is high. In this case, as the VCO gain is high, and ΔVt is low, a deadlock is unlikely to occur in the PLL.

On the other hand, as indicated by a sign 602 in FIGS. 6 and 7, when the CH is low, the capacitor bank is high, and the VCO gain (Kvco) is low. In this case, as the VCO gain is low, and ΔVt is high, a deadlock is likely to occur in the PLL. That is, as indicated in the above (equation 2), it can be seen that when the VCO gain (Kvco) is reduced, ΔVt increases, and thus a deadlock caused by a VCO temperature drift is likely to occur in the PLL. It is thus necessary to take measures against a deadlock in the PLL circuit that operates in a wideband such as a TV tuner.

### <PLL Synthesizer According to Basic Example 2>

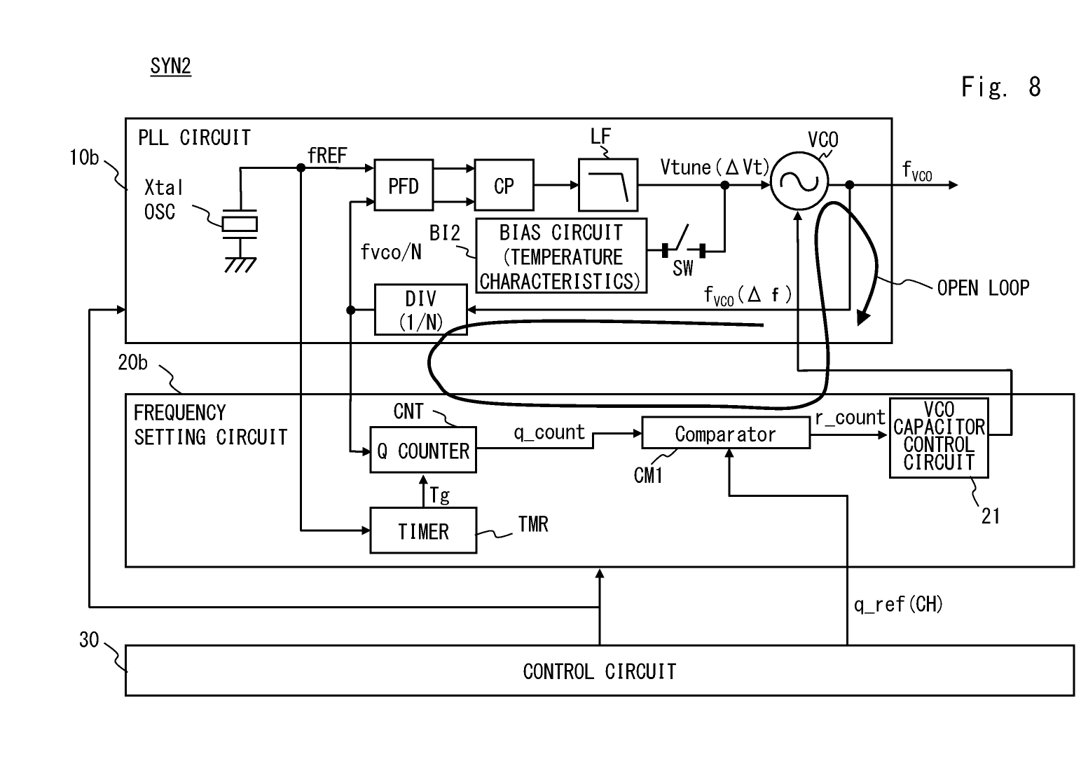

Next, a PLL synthesizer according to a basic example 2, which is based on the technique disclosed in Japanese Unexamined Patent Application Publication No. 2004-7433 and is the basics of the first embodiment, will be described. FIG. 8 shows a configuration of a PLL synthesizer SYN2 according to the basic example 2. As shown in FIG. 8, the PLL synthesizer SYN2 according to the basic example 2 includes a PLL circuit 10b and a frequency setting circuit 20b.

A configuration of the PLL circuit 10b according to the basic example 2 is basically the same as that of the PLL circuit 10a according to the basic example 1. The PLL circuit 10b according to the basic example 2 includes a crystal oscillator OSC (Xtal OSC), a phase frequency detector PFD, a charge pump CP, a loop filter LF, a voltage control oscillator VCO, a frequency divider DIV, and a bias circuit BI2. The bias circuit BI2 according to the basic example 2 is a DC voltage source circuit having temperature characteristics (temperature characteristics and temperature dependency). The temperature characteristics included in the voltage source reduce a range of voltage fluctuation in the VCO control voltage Vtune when a temperature is fluctuated.

The frequency setting circuit 20b calibrates the PLL circuit (VCO) and sets a frequency. The frequency setting circuit 20b according to the basic example 2 includes a timer TMR, a Q counter CNT, a comparator CM1, and a VCO capacitor control circuit 21.

The timer TMR generates a trigger signal Tg that specifies a count period of the Q counter CNT based on the reference frequency signal fREF. The Q counter CNT counts a frequency of a frequency-divided signal (fvco/N or fvco) that is divided by the frequency divider DIV for a period specified by the trigger signal Tg of the timer TMR and then generates a count value q_count.

A count value q_ref of a frequency according to the CH is input from the control circuit 30 to the comparator CM1. Then, the comparator CM1 compares the count value q_ref with the count value q_count of the Q counter CNT and then generates a comparison result r_count. The VCO capacitor control circuit 21 controls the capacitor bank of the voltage control oscillator VCO based on the comparison result r_count of the comparator CM1. For example, the VCO capacitor control circuit 21 is a calibration processing unit that calibrates the voltage control oscillator VCO based on a difference between the count value q_ref (or the oscillation frequency) and the count value q_count (or the oscillation frequency). The VCO oscillation frequency can be set to a desired frequency by the calibration.

In the basic example 2, the switch SW is previously turned on, the bias circuit BI2 sets the VCO control voltage Vtune to a predetermined voltage, the Q counter CNT counts frequencies of respective CHs, and the control circuit 30 (a storage circuit) stores a count value as the count value q_ref. While the PLL is in a normal operation, the count value q_ref according to the reception CH is compared with the count value q_count in order to control the capacitor bank of the voltage control oscillator VCO.

In the basic example 2, the voltage control oscillator VCO, the frequency divider DIV, the Q counter CNT, the comparator CM1, and the VCO capacitor control circuit 21 constitute an open loop that performs calibration. In the calibration, the open loop of the PLL counts the VCO oscillation frequency fvco and compares it with the count value (q_ref) of an expected frequency. The VCO capacitor control circuit 21 selects a VCO capacitor bank in which a difference between the VCO oscillation frequency fvco and the expected frequency is lower than or equal to an allowable value. During the calibration, the switch SW is turned on (the loop filter LF and VCO are disconnected), an open loop is formed, and then the calibration is performed. After the calibration, the switch SW is turned off (the loop filter LF and VCO are connected), a closed loop is formed, a normal operation is started, and then the PLL circuit is locked.

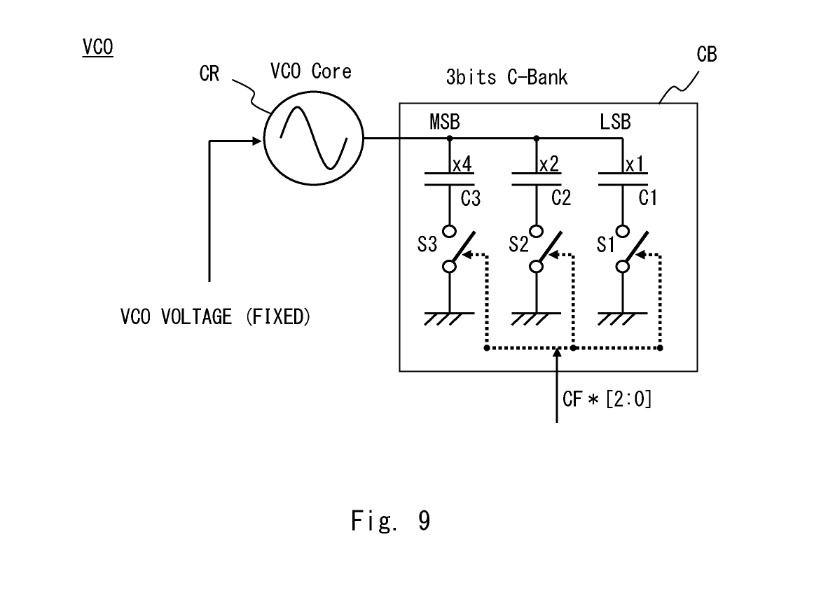

FIGS. 9 to 11 show specific examples of capacitor bank selection during the calibration. In this example, as shown in FIG. 9, the voltage control oscillator VCO includes a VCO core CR and a capacitor bank CB. The capacitor bank CB is a three-bit capacitor bank and includes capacitive elements C1 to C3 and switches S1 to S3 corresponding to the bits. The capacitor elements C1 to C3 and the switches S1 to S3, respectively, are connected in series, and the capacitor elements and the switches are connected between the VCO core CR and GND.

Capacitances of the capacitive elements are weighted according to the bits, respectively. When C1 (a capacitance of the capacitive element C1), which is a LSB, is used as a reference, the capacitive element C2 is CF1×2, and the capacitive element C3 is CF1×4. The switches S1 to S3 are turned on or off according to control data CF[2:0], and a capacitance of the capacitor bank CB is switched.

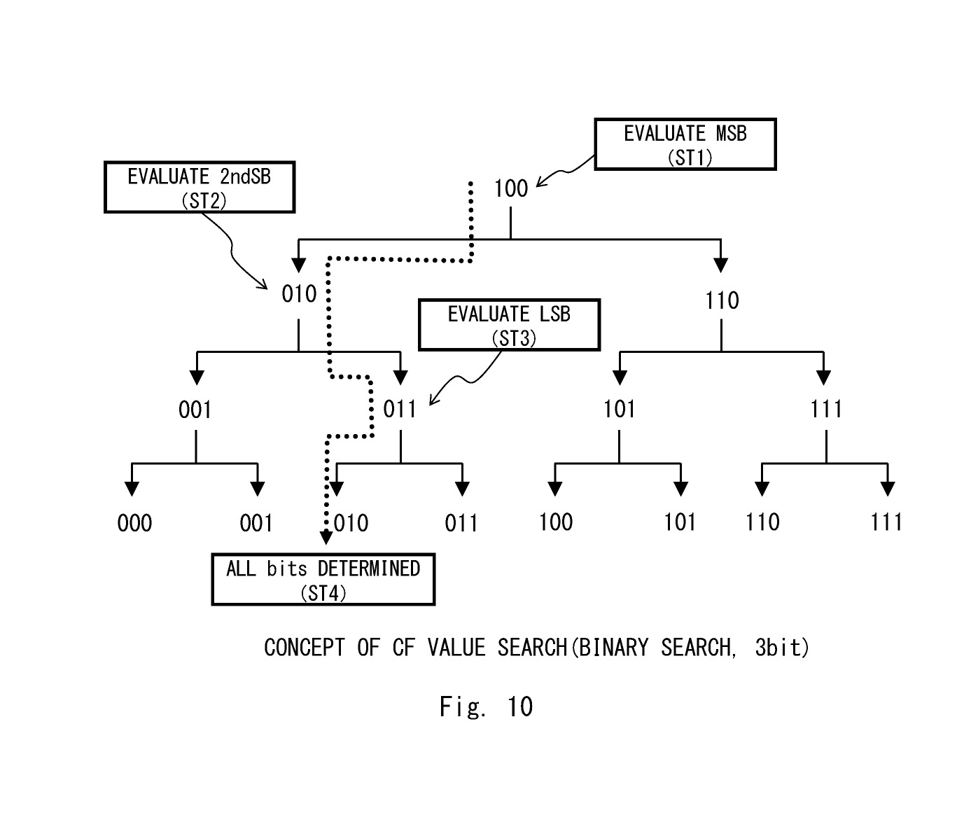

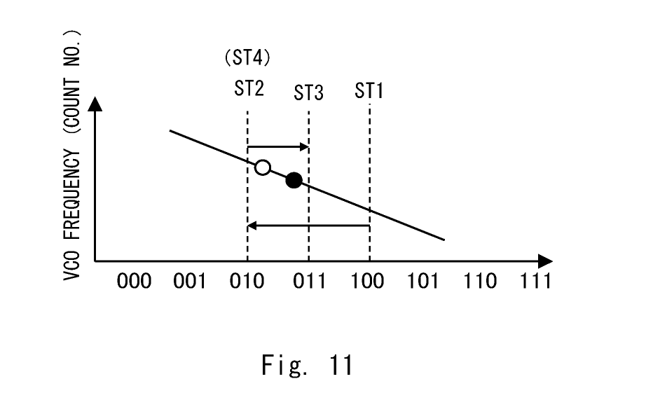

As shown in FIGS. 10 and 11, in the calibration, the capacitor bank in the LC VCO is optimized by binary search so that the VCO oscillation frequency fvco will become close to an expected value. In this example, the capacitor bank is selected by [100], in which MSB=1, and the VCO oscillation frequency fvco is evaluated (ST1). When the expected value is smaller than the VCO oscillation frequency fvco in ST1, the capacitor bank is selected by [010], in which the second bit=1, and then the VCO oscillation frequency fvco is evaluated (ST2). When the expected value evaluated that it is greater than the VCO oscillation frequency fvco in ST2, the capacitor bank is selected by [011], in which LSB=1, and then the VCO oscillation frequency fvco is evaluated (ST3). When the expected value is evaluated that it is smaller than the VCO oscillation frequency fvco in ST3, all bits are determined by [010], in which LSB=0 (ST4).

In the basic example 2, in the PLL circuit that uses the voltage control oscillator VCO having a plurality of VCO oscillation frequencies, the switch SW is switched to a side of the bias circuit BI2 (DC voltage source) to perform automatic calibration. At this time, the VCO control voltage Vtune is fixed to a voltage value of the bias circuit BI2. A temperature fluctuation in the bias circuit BI2 can cancel a temperature fluctuation in the VCO oscillation frequency fvco.

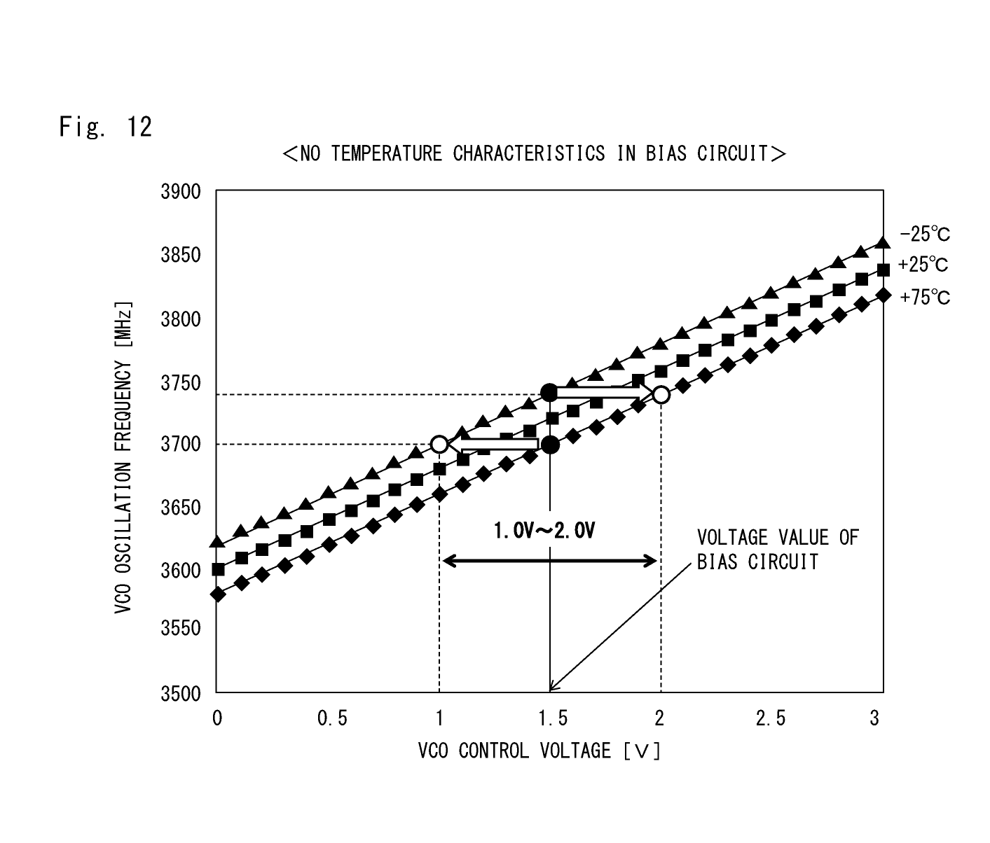

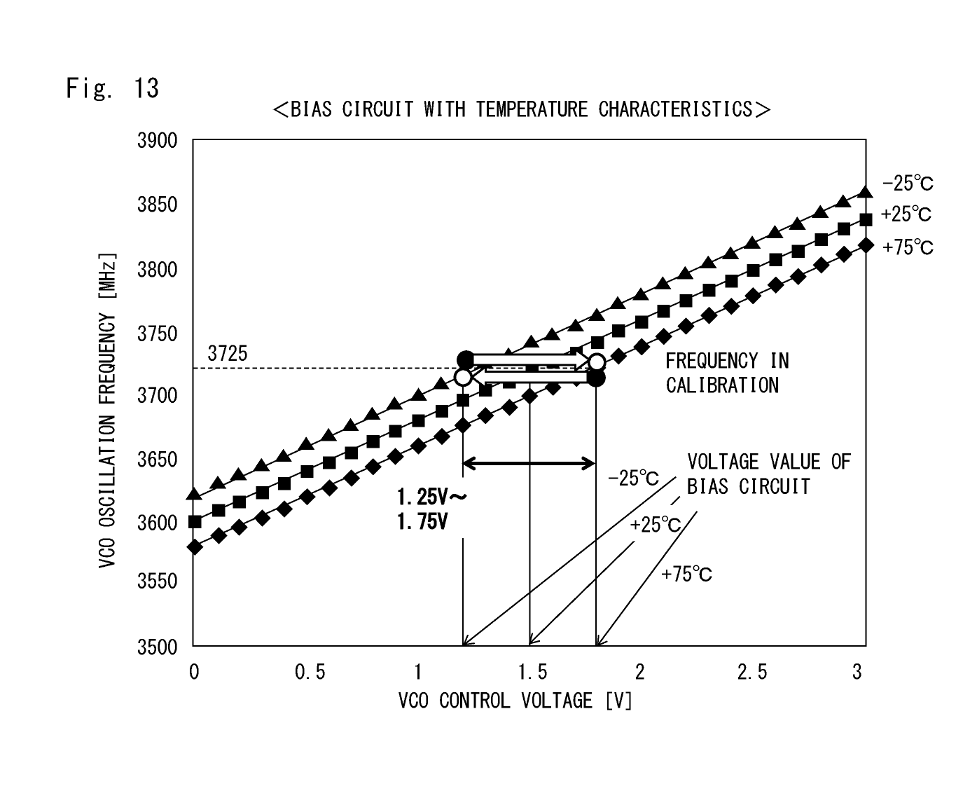

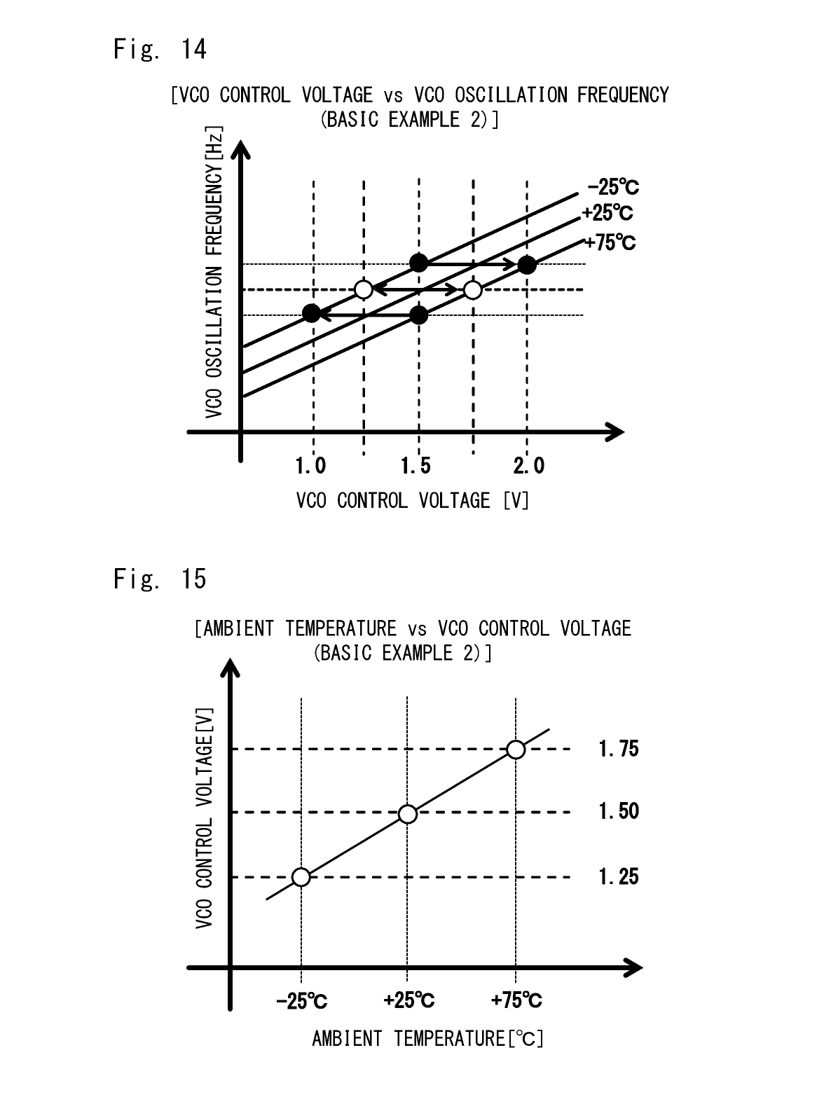

FIGS. 12 and 13 show changes in the VCO control voltage Vtune according to temperature fluctuations in the basic examples 1 and 2. FIG. 14 shows a relationship between the VCO control voltage and the VCO oscillation frequency when a temperature is fluctuated in the basic example 2, and FIG. 15 shows a relationship between the ambient temperature and the VCO control voltage when a temperature is fluctuated in the basic example 2.

With the bias circuit of the VCO without temperature characteristics as in the basic example 1, as shown in FIG. 12, when the VCO control voltage Vtune is set to 1.5 V at the temperature of +25 Celsius degrees, and the temperature is fluctuated between ±50 Celsius degrees, a range of fluctuation in the VCO control voltage Vtune is 1.0 V to 2.0 V (1.0 V width).

On the other hand, with the bias circuit of the VCO having temperature characteristics as in the basic example 2, as shown in FIG. 13, if a temperature at the time of power-on is −25 Celsius degrees, and the VCO control voltage Vtune at that time is 1.25 V, when the temperature increases to become +75 Celsius degrees, the VCO control voltage Vtune will become 1.75 V at the oscillation frequency=3725 MHz. This is the same result obtained in the environment where the temperature at the time of power-on is +75 Celsius degrees, and the voltage value of the bias circuit BI2 is 1.75 V. Specifically, in the basic example 2, when the temperature is fluctuated between ±50 Celsius degrees, the range of fluctuation in the VCO control voltage Vtune is 1.25 V to 1.75 V (0.5 V width). In a manner similar to FIG. 13, FIGS. 14 and 15 show relationships between the temperature and fluctuations in the VCO control voltage Vtune.

In the basic example 2, the temperature fluctuation in the VCO oscillation frequency fvco is canceled by the temperature fluctuation in the bias circuit BI2 that supplies the initial value of the VCO control voltage Vtune. As shown in FIG. 15, the VCO control voltage Vtune according to the temperature is generated by the temperature characteristics of the bias circuit BI2. It is thus necessary to adjust the voltage control oscillator VCO with the temperature characteristics of the bias circuit BI2 in the basic example 2, thereby making accurate temperature compensation difficult.

Further, in the basic example 2, although the temperature fluctuation values of the VCO control voltage Vtune differ according to the CH or the like, the temperature fluctuations in the voltage control oscillator VCO is uniformly compensated. It is thus not possible to appropriately compensate temperatures. Further, in the basic example 2, the bias circuit (the voltage source circuit) used to obtain desired temperature characteristics for the VCO control voltage Vtune needs to be added, thereby leading to an increase in the circuit area.

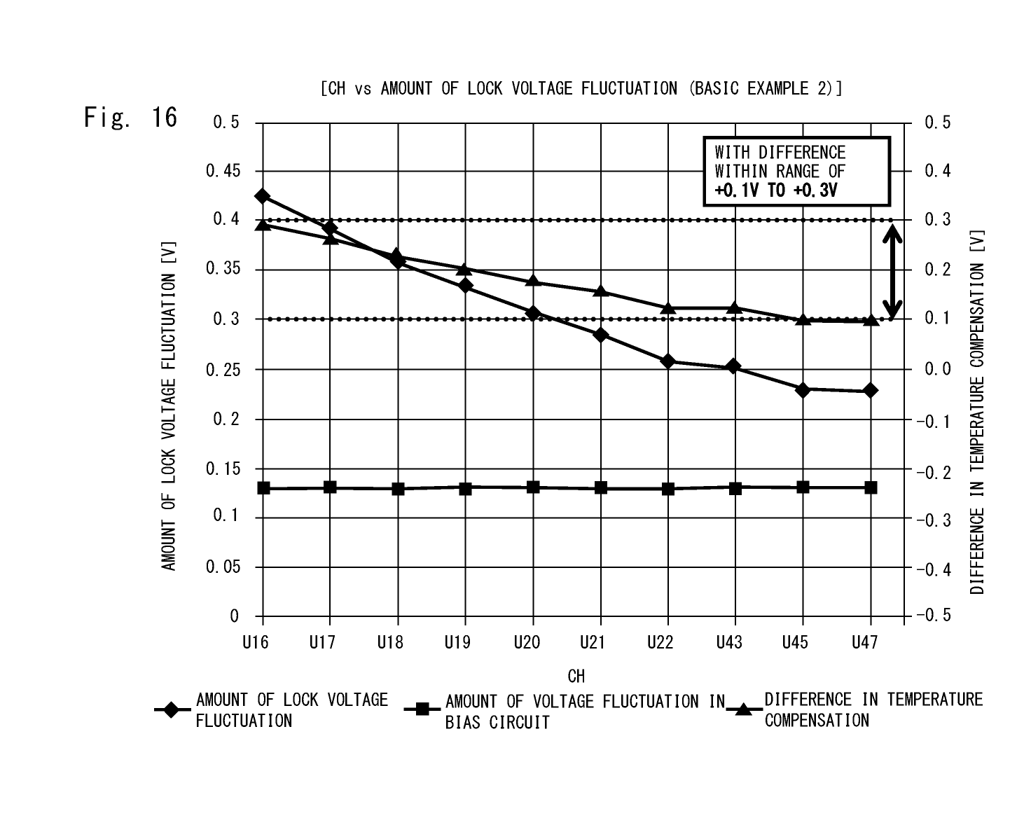

In the basic example 2, “a deviation in the control voltage caused by a temperature fluctuation in the VCO” and “a temperature fluctuation in a voltage source circuit that supplies an initial voltage” are adjusted in order to reduce a temperature fluctuation in the VCO control voltage Vtune. However, with such a configuration, as there is no correlation between the parameters, canceling out of the temperature fluctuations in circuits may not be effective when there are variations in the circuits. FIG. 16 shows a relationship between CHs and an amount of fluctuations in the lock voltage when the bias circuit includes the temperature characteristic as in the basic example 2. FIG. 16 shows an example in which VDD=1.2 V and the ambient temperature changes from −40 Celsius degrees to +85 Celsius degrees. As shown in FIG. 16, when the bias circuit includes the temperature characteristics, an error in the adjustment between the lock voltage and the temperature fluctuation appears as a difference in the temperature compensation voltage. The difference in the temperature compensation is within the range of +0.1 V to +0.3 V. It is therefore difficult for the basic example 2 to handle fluctuations in the VCO control voltage Vtune in a wideband.

### <PLL Synthesizer According to First Embodiment>

In this embodiment, before the calibration that is performed in the basic example 2 is executed, a temperature fluctuation from a normal temperature of an ambient temperature is estimated, and the fluctuation in the temperature is fed back to the VCO control voltage at the time of executing the calibration. The feedback is performed in a digital manner and not in an analog manner. The feedback optimizes the VCO control voltage, and a deadlock in the PLL can be avoided even with temperature fluctuations in a wide range and in a wideband operation. As the estimation of the temperature fluctuation does not require an additional circuit and can use an algorithm of the calibration that is performed in the basic example 2, the circuit area and current consumption will not be increased.

In particular, in this embodiment, before the calibration (CAL) for setting a frequency of the PLL is executed, an evaluation as to whether the ambient temperature is higher or lower than the normal temperature is performed. When the ambient temperature is high, an initial voltage of the VCO control voltage Vtune is increased so that the PLL can operate even when the ambient temperature is shifted to a low temperature side. Whereas when the ambient temperature is low, the initial voltage of the VCO control voltage Vtune is reduced so that the PLL can operate even when the ambient temperature is shifted to a high temperature side.

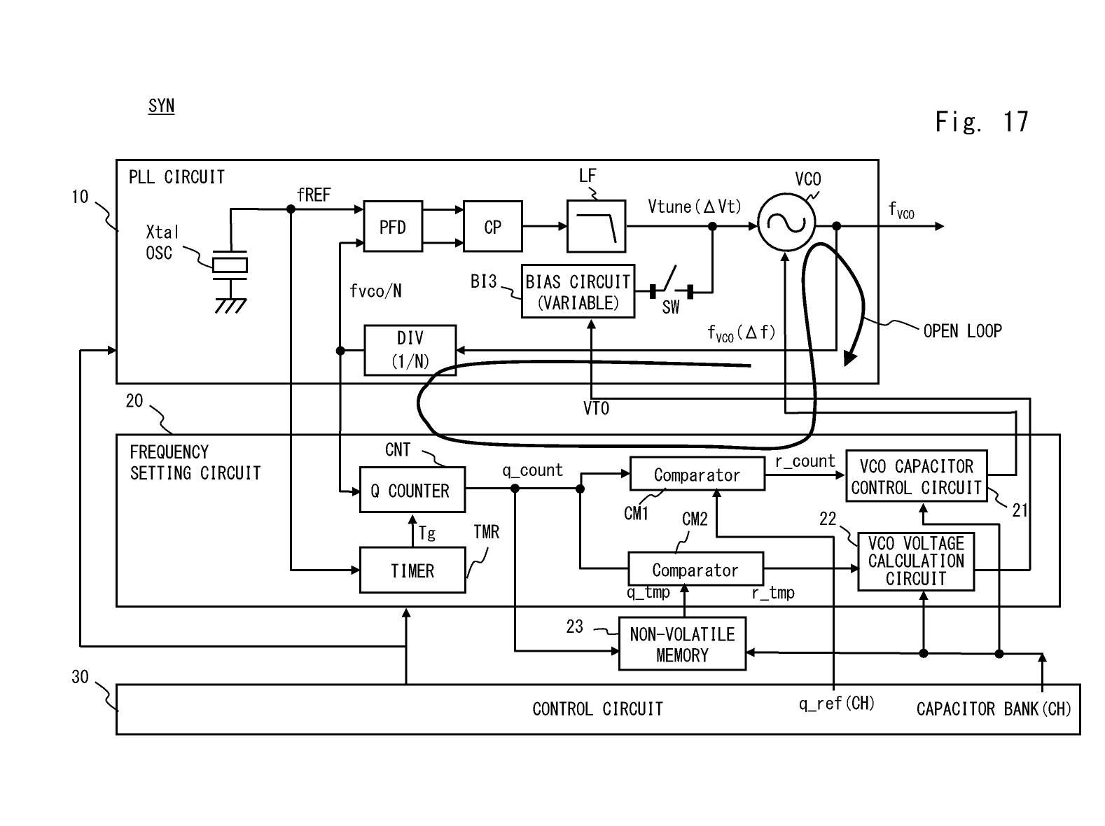

FIG. 17 shows a configuration of a PLL synthesizer SYN according to this embodiment. As shown in FIG. 17, SYN according to this embodiment includes a PLL circuit 10 and a frequency setting circuit 20.

A configuration of the PLL circuit 10 according to this embodiment is basically the same as that of the PLL circuit 10 according to the basic examples 1 and 2. The PLL circuit 10 according to this embodiment includes a crystal oscillator OSC, a phase frequency detector PFD, a charge pump CP, a loop filter LF, a voltage control oscillator VCO, a frequency divider DIV, and a bias circuit BI3. The bias circuit BI3 according to this embodiment generates the VCO control voltage Vtune according to control by the frequency setting circuit 20 (the VCO voltage calculation circuit 22).

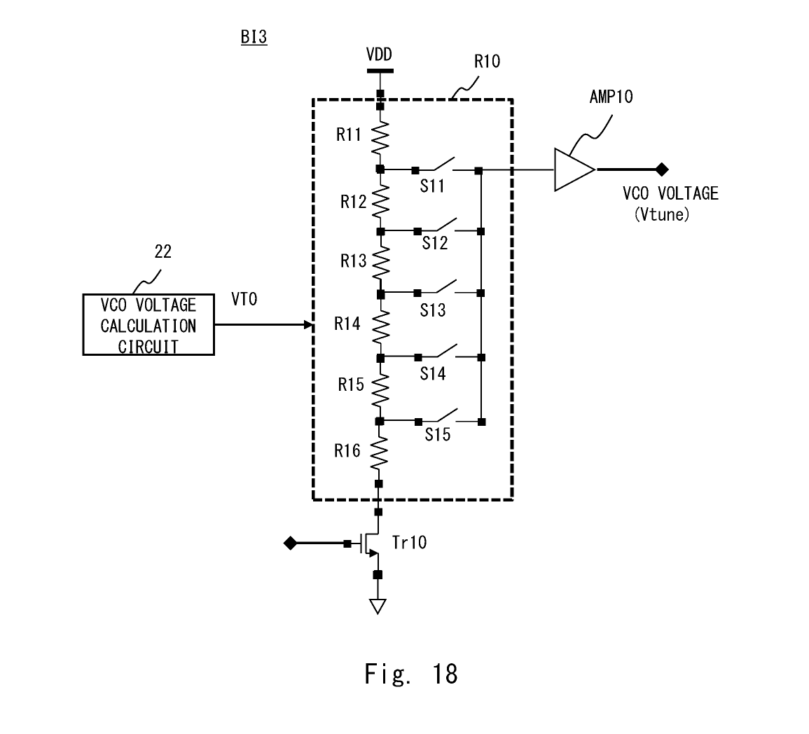

FIG. 18 shows a circuit configuration example of the bias circuit BI3 according to this embodiment. FIG. 18 shows an example of the bias circuit BI3 in which resistors are switched. In this example, a bias between VDD and GND is divided by a plurality of resistors to adjust a voltage value of the VCO control voltage Vtune.

As shown in FIG. 18, the bias circuit BI3 includes a resistance divider R10, a transistor Tr10, and a voltage follower AMP 10. The resistance divider R10 includes resistors R11 to R16 and switches S11 to S15. The resistors R11 to R16 are connected in series between VDD and the transistor Tr10. The switches S11 to S15 connect intermediate nodes between the resistors R11 to R16 to the voltage follower AMP 10. The switches S11 to S15 are turned on or off according to a control signal VT0 (a digital value) from the VCO voltage calculation circuit 22 in order to switch the VCO control voltage Vtune. Then, the VCO control voltage Vtune can be accurately set by the digital value.

Further, as shown in FIG. 17, in a manner similar to the frequency setting circuit according to the basic example 2, the frequency setting circuit 20 according to this embodiment includes a timer TMR, a Q counter CNT, a comparator CM1, and a VCO capacitor control circuit 21 and further includes a comparator CM2 and a VCO voltage calculation circuit 22.

In this embodiment, the frequency setting circuit 20 further includes a non-volatile memory 23. The non-volatile memory (a temperature table storage unit or an oscillation frequency storage unit) 23 stores a temperature table TBL and a frequency count value q_tmp at a normal temperature. The non-volatile memory 23 is provided in a radio signal processing device RFIC or a baseband processing device BBIC.

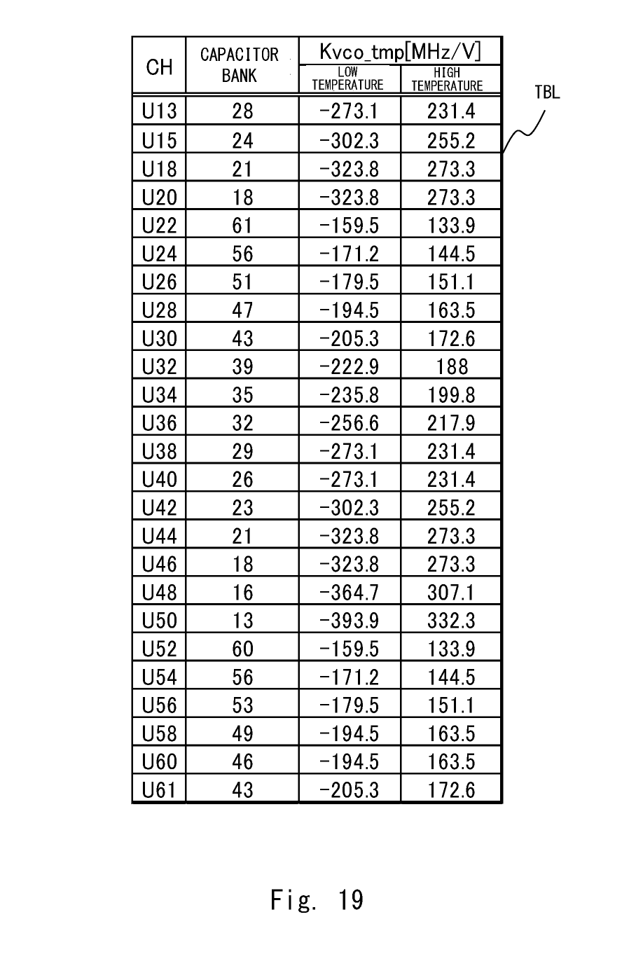

FIG. 19 shows an example of the temperature table TBL according to this embodiment. As shown in FIG. 19, the temperature table TBL associates CHs, capacitor banks, and Kvco_tmp (VCO gain) at low and high temperatures. Note that an approximation expression (linear approximation, polynomial approximation etc.) may be used instead of the temperature table to calculate Kvco_tmp for the respective capacitor banks. A memory capacity can be reduced by the approximation expression.

As shown in FIG. 17, the frequency count value q_tmp at the normal temperature is input to the comparator CM2 from the non-volatile memory 23. The comparator CM2 compares the count value q_tmp with the count value q_count of the Q counter CNT and then generates a comparison result r_tmp. The VCO voltage calculation circuit (the control voltage setting unit) 22 controls the bias circuit BI3 by the control signal VT0 based on the comparison result r_tmp of the comparator CM2 and then sets the VCO control voltage Vtune. For example, although a temperature fluctuation can be surely detected using a difference in the count values for the VCO oscillation frequencies, the VCO control voltage may be set using a difference in the VCO oscillation frequencies. Note that the comparator CM2 and the VCO voltage calculation circuit 22 may constitute a control voltage setting unit that sets the VCO control voltage based on the count value q_tmp and the count value q_count.

In this embodiment, in addition to the calibration performed in the basic example 2, temperature fluctuation estimation is performed. To be more specific, a temperature fluctuation is estimated from the VCO oscillation frequency of the corresponding capacitor bank at the normal temperature that has been previously stored in the non-volatile memory and the temperature table (Kvco table) created at the time of the evaluation, and then the VCO control voltage Vtune at the time of executing the calibration is calculated. As a circuit to be added can be a new logical circuit, there will be a small influence on the circuit area and current consumption.

### <Operation of First Embodiment>

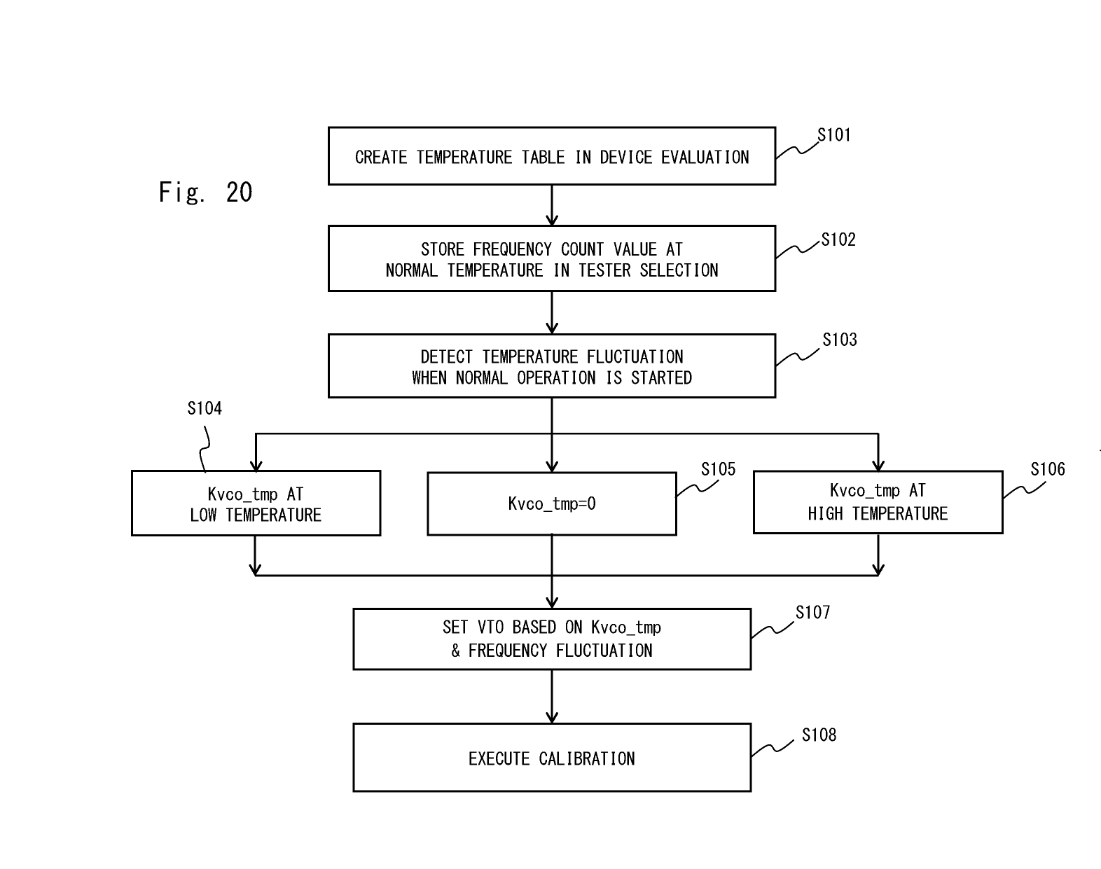

FIG. 20 is a flowchart showing an operation of estimating a temperature fluctuation according to this embodiment. In FIG. 20, in addition to the calibration (S108) that is performed in the basic example 2, an algorithm for temperature fluctuation estimation (S101 to S107) is included. The step S101 is executed in device evaluation of a semiconductor device, the step S102 is executed when the semiconductor device selects a tester, and steps S103 to S108 are executed when the semiconductor device is actually in a normal operation.

Firstly, in device evaluation of the semiconductor device, the PLL synthesizer SYN creates a temperature table (S101). The control circuit 30 creates an open loop, measures Kvco at a high temperature and Kvco at a low temperature for each of the CHs (the capacitor banks), and generates the temperature table TBL as shown in FIG. 19. The capacitor bank corresponding to the CH is previously determined. The CH and the capacitor bank are set, and Kvco in a low temperature environment (e.g., −25 Celsius degrees) and Kvco in a high temperature environment (e.g., +75 Celsius degrees) are calculated. For example, Kvco can be obtained by f/Vt. In the device evaluation, the number of semiconductor devices is increased to N in order to perform the evaluation, and an average value (kvco/N) of measurement values that have been measured in all of the increased semiconductor devices is stored in the table.

Next, in tester selection of the semiconductor devices, the PLL synthesizer SYN stores a frequency count value at a normal temperature (S102). In a state in which the open loop is formed, the Q counter CNT measures the frequency count value q_count at the normal temperature (e.g., +25 Celsius degrees) and stores it as the frequency count value q_tmp in the non-volatile memory 23. For example, the frequency count value q_count is measured in a state in which the setting is: Vtune=0.45 V (the initial value). In the tester selection, the frequency count value q_count that is measured in the tester semiconductor device that has been selected from among all the semiconductor devices is stored in the non-volatile memory 23.

Note that S101 and S102 may be executed in the tester selection of the semiconductor device. As fluctuations in the temperature caused by variations in the samples can be monitored, an error in the temperature table and individual samples can be reduced. Additionally, it will be unnecessary to create a reference temperature table by increasing the sample size to perform the evaluation.

Next, when the semiconductor device starts the normal operation, the PLL synthesizer SYN detects a temperature fluctuation (S103). When the normal operation is started, the current frequency count value q_count is measured, and the current frequency count value q_count is compared with the count value at the normal temperature in order to evaluate as to whether or not the temperature is high or low before the calibration is started in a state in which the open loop is formed.

For example, in a state in which the setting is: Vtune=0.45 V (the initial value), the comparator CM2 compares the current count value q_count measured by the Q counter CNT with the count value q_tmp at the normal temperature that is stored in the non-volatile memory. When the count value q_count is greater than the count value q_tmp, the VCO voltage calculation circuit 22 determines that the current temperature is lower than the normal temperature. When the count value q_count is smaller than the count value q_tmp, the VCO voltage calculation circuit 22 determines that the current temperature is higher than the normal temperature. When the count value q_count is equal to the count value q_tmp, the VCO voltage calculation circuit 22 determines that the current temperature is the normal temperature.

Alternatively, the VCO voltage calculation circuit 22 may detect (estimate) a temperature fluctuation from the normal temperature by a frequency fluctuation ΔfVCO that is expressed by the following (equation 3).

ΔfVCO=fvco_{MON}−fvco_{REF} (Equation 3)

In the equation 3, fvco_{MON} is the monitored VCO oscillation frequency (or the count value), and fvco_{REF} is the VCO oscillation frequency (or the count value) which is a reference (at the normal temperature). The VCO oscillation frequency can be calculated using the count value q_count. When ΔfVCO>0, the current temperature is determined as being a low temperature. When ΔfVCO<0, the current temperature is determined as being a high temperature. When ΔfVCO=0, the current temperature is determined as being the normal temperature.

Next, the PLL synthesizer SYN determines Kvco_tmp (VCO gain) based on the detected temperature fluctuation (S104 to S106). The VCO voltage calculation circuit 22 determines Kvco_tmp based on the CH (the capacitor bank), the above temperature fluctuation, and the temperature table. The Kvco_tmp that suits the temperature condition is selected according to the CH (the capacitor bank) to use by referring to the temperature table.

When the current temperature is lower than the normal temperature (when the count value q_count is greater than the count value q_tmp, which is ΔfVCO>0), the VCO voltage calculation circuit 22 selects a low temperature Kvco_tmp from the temperature table TBL (S104). When the current temperature is higher than the normal temperature (when the count value q_count is greater than the count value q_tmp, which is ΔfVCO<0), the VCO voltage calculation circuit 22 selects a high temperature Kvco_tmp from the temperature table TBL (S106). When the current temperature is the normal temperature (when the current value q_count is equal to the count value q_tmp, which is ΔfVCO=0), Kvco_tmp=0 is set (S105).

Next, the PLL synthesizer SYN sets Vtune based on the determined Kvco_tmp and the frequency fluctuation ΔfVCO (S107). The VCO voltage calculation circuit 22 calculates a control voltage fluctuation ΔVt by the determined Kvco_tmp and the frequency fluctuation ΔfVCO using the following (equation 4). Note that the control voltage fluctuation ΔVt may be calculated by the count value q_count instead of the frequency.

ΔVt=ΔfVCO/Kvco_tmp (Equation 4)

The VCO voltage calculation circuit 22 calculates ΔVt according to the CH (the capacitor bank) and sets the bias voltage, a temperature of which has been compensated. The VCO voltage calculation circuit 22 calculates the control voltage Vtune (the control signal VT0) to be set from the control voltage fluctuation ΔVt using the following (equation 5) and then sets the control voltage Vtune to the bias circuit BI3. Note that Vt_def is the initial value of Vtune (the value at the normal temperature).

Vtune=Vt_def+ΔVt (Equation 5)

Next, the PLL synthesizer SYN executes calibration that is performed in the basic example 2 (S108). In a state in which the bias circuit BI3 applies the VCO control voltage Vtune in the setting of S107 and where the open loop is formed as in the basic example 2, the calibration is started in order to set a frequency of the voltage control oscillator VCO. Note that it is not necessary to execute the calibration except when the CH is changed or the power is on or off. When the calibration is completed, a closed loop is formed, and the PLL circuit starts the normal operation.

### <Advantage of First Embodiment>

As has been described with reference to FIG. 5 of the basic example 1, when a temperature is shifted to become a high or a low temperature from the initial value of the lock voltage, the VCO oscillation frequency is fluctuated. As the PLL circuit attempts to converge the VCO oscillation frequency to a desired value, a loop can be maintained by fluctuating the VCO control voltage. However, when an influence of the fluctuation in the VCO control voltage becomes greater than a range of the lock voltage, the PLL circuit is unlocked.

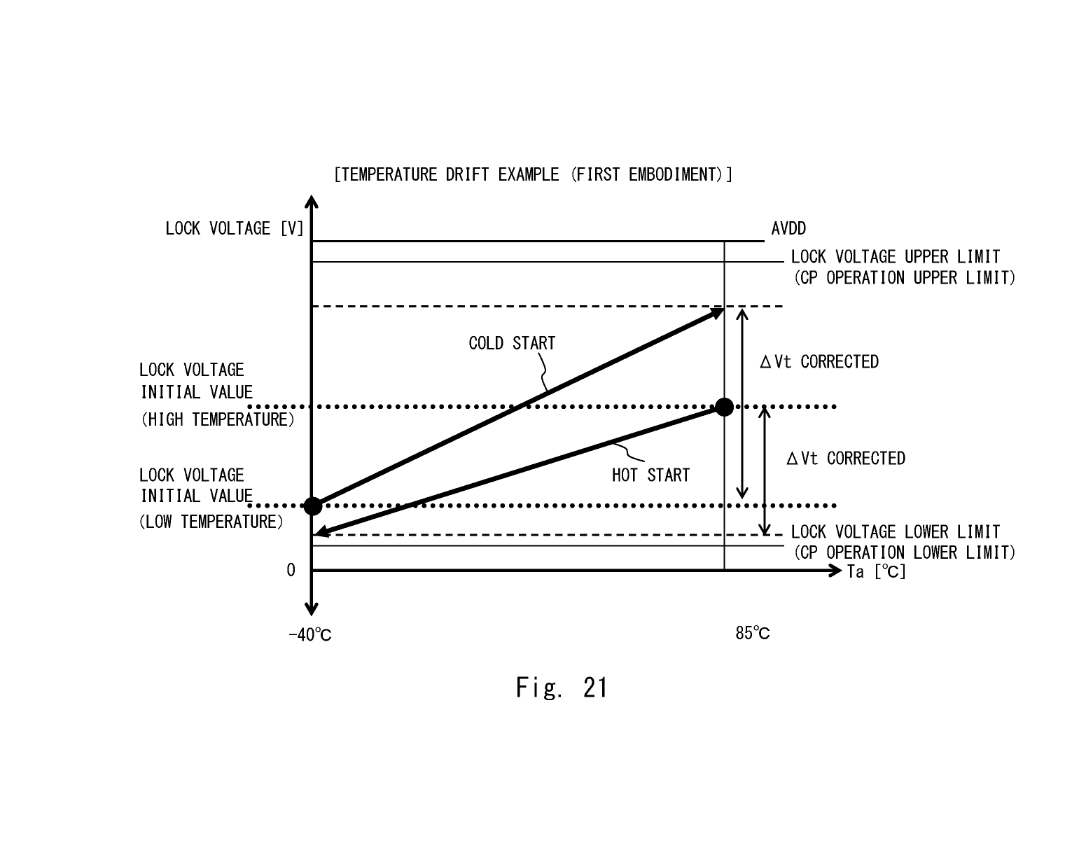

In order to prevent such a situation, in this embodiment, as shown in FIG. 21, the initial value of the lock voltage is increased or reduced according to the ambient temperature, so that the temperature will be within a range of the upper limit to the lower limit of the lock voltage even when it is fluctuated.

As a specific compensation method, the VCO oscillation frequency before the calibration operation is directly monitored in order to estimate a fluctuation in the ambient temperature. Circuit stability that is deteriorated by a fluctuation in the ambient temperature after the PLL is locked can be compensated by digitally controlling the initial value of the bias circuit using a result of the estimation.

As shown in FIG. 21, when the PLL circuit is cold-started, as the temperature is low, the initial value of the lock voltage is set to be a low value. Then, the ambient temperature is fluctuated from −40 Celsius degrees to 85 Celsius degrees, and even when the lock voltage increases from the initial value by ΔVt (the initial value+ΔVt) according to the temperature, the lock voltage will not exceed the upper limit, and thus a deadlock will not occur in the PLL. Whereas when the PLL circuit is hot-started, as the temperature is high, the initial value of the lock voltage is set to be a high value. Then, the ambient temperature is fluctuated from 85 Celsius degrees to −40 Celsius degrees, and even when the lock voltage is reduced from the initial value by ΔVt (the initial value−ΔVt) according to the temperature, the lock voltage will not fall below the lower limit, and thus a deadlock will not occur in the PLL.

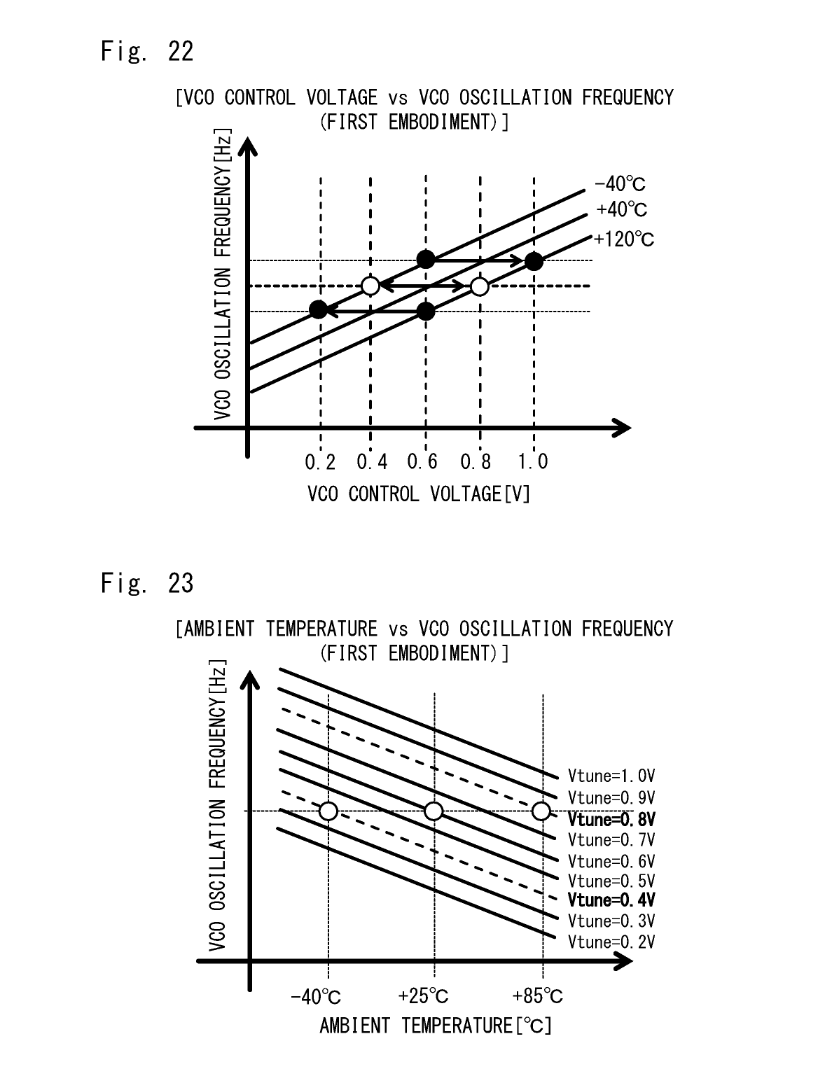

As has been described with reference to FIGS. 14 and 15 according to the basic example 2, when the bias circuit includes the temperature characteristics, it is necessary to adjust the voltage control oscillator VCO with the temperature characteristics of the bias circuit. On the other hand, FIG. 22 shows a relationship between the VCO control voltage and the VCO oscillation frequency when a temperature is fluctuated according to this embodiment. FIG. 23 shows a relationship between the ambient temperature and the VCO oscillation frequency according to this embodiment. In this embodiment, when a temperature (a normal temperature) is fluctuated between ±80 Celsius degrees, the range of fluctuation in the VCO control voltage Vtune is 0.4 V to 0.8 V (0.4 width). Further, in this embodiment, as the temperature fluctuation in the VCO oscillation frequency can be directly controlled by the VCO control voltage Vtune, the adjustment as in the basic example 2 is unnecessary, thereby making accurate temperature compensation possible.

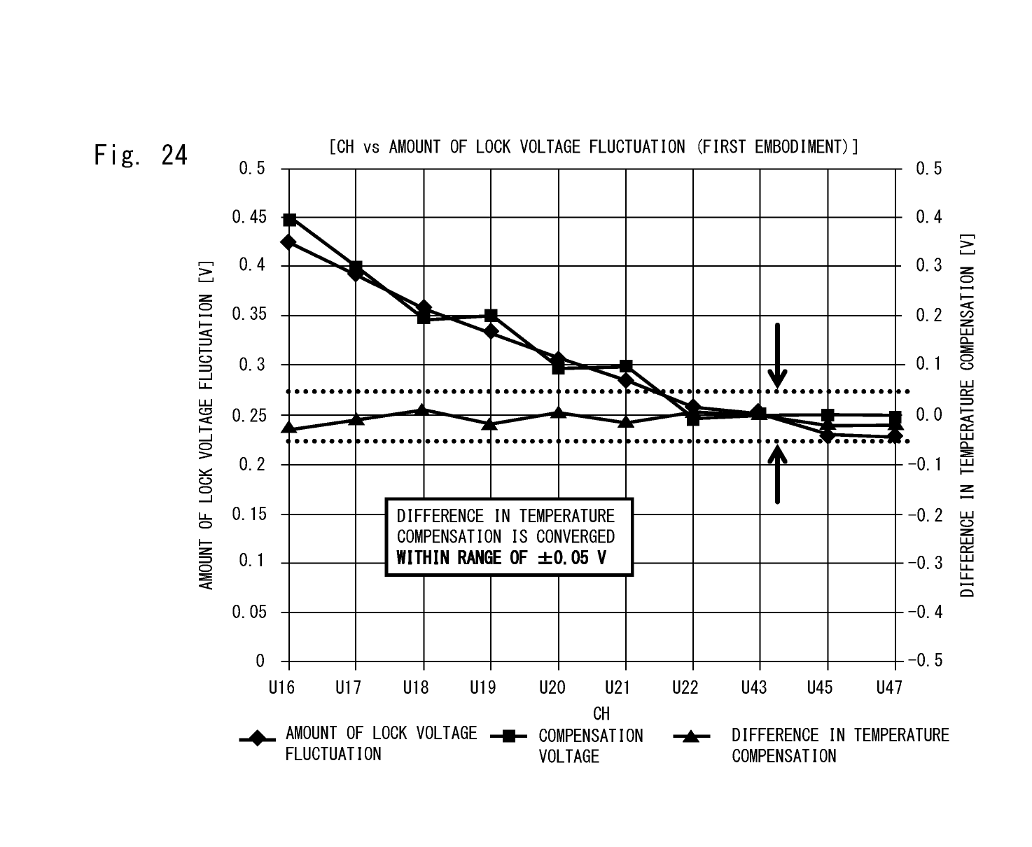

As has been described with reference to FIG. 16 of the basic example 2, when the bias circuit includes the temperature characteristics, an error in the adjustment between the lock voltage and the temperature fluctuation appears as a difference in the temperature compensation voltage. On the other hand, FIG. 24 shows a relationship between CHs and an amount of lock voltage fluctuations. In this embodiment, as the VCO control voltage is switched according to the temperature, the difference in the temperature compensation is converged within a range of ±0.05 V. That is, in this embodiment, the temperature fluctuation in the VCO oscillation frequency is monitored, and a compensation voltage (in 0.05 V increments) according to the temperature fluctuation is applied. By doing so, an optimal compensation voltage for each condition of a Vtune fluctuation can be applied.

To summarize the advantages of this embodiment, a first advantage is that the ambient temperature can be estimated by monitoring the VCO oscillation frequency before a lock operation is started on the PLL.

A second advantage is that by estimating the ambient temperature, as mentioned in the first advantage, and then fluctuating the initial value of the VCO control voltage according to a temperature fluctuation from the normal temperature, a Pull-in range of the VCO can be enlarged and optimized, and thus avoiding a deadlock in the PLL when a temperature is fluctuated in a wide range and in a wideband operation. Thus, this embodiment can be applied to TV tuners, in-vehicle products, and mobile phones that do not tolerate the PLL to be unlocked in an environment where a temperature is greatly fluctuated.

A third advantage is that a circuit area and current consumption will not be increased because in order to achieve the first and second advantages, a circuit such as a temperature sensor will not be needed and only a new logic circuit needs to be included in addition to the circuits according to the basic examples.

Although the invention carried out by the present inventor has been described in detail based on the embodiments, it is obvious that the present invention is not limited to the above embodiments, and various modifications can be made without departing from the scope of the invention.

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A semiconductor device comprising:
a PLL circuit comprising a voltage control oscillation circuit configured to control an oscillation frequency according to a control voltage;
an oscillation frequency storage unit configured to previously store the oscillation frequency at a first temperature;
a control voltage setting unit configured to set the control voltage based on a difference between the oscillation frequency at a second temperature and the stored oscillation frequency; and
a calibration processing unit configured to calibrate the voltage control oscillation circuit in a state in which the control voltage is set so that the oscillation frequency will become a predetermined frequency.

2. The semiconductor device according to claim 1, wherein the control voltage setting unit is configured to estimate a temperature change from the first temperature based on the difference and then sets the control voltage based on the estimated temperature change.

3. The semiconductor device according to claim 2, further comprising a temperature table storage unit configured to store a temperature table, the temperature table associating the control voltage at a temperature lower than the first temperature with the control voltage at a temperature higher than the first temperature, wherein the control voltage setting unit is configured to refer to the temperature table and set the control voltage according to the estimated temperature change.

4. The semiconductor device according to claim 1, wherein
the oscillation frequency of the voltage control oscillation circuit can be selected from among a plurality of oscillation frequencies, and
the control voltage setting unit is configured to set the control voltage based on a difference between the oscillation frequency at the second temperature and the stored oscillation frequency and based on the selected oscillation frequency.

5. The semiconductor device according to claim 4, wherein the control voltage setting unit is configured to estimate a temperature change from the first temperature based on the difference between the oscillation frequency at the second temperature and the stored oscillation frequency and set the control voltage based on the estimated temperature change and the selected oscillation frequency.

6. The semiconductor device according to claim 5, further comprising a temperature table storage unit configured to store a temperature table, the temperature table associating the control voltage at a temperature lower than the first temperature with the control voltage at a temperature higher than the first temperature for each of the oscillation frequencies, wherein the control voltage setting unit is configured to refer to the temperature table and set the control voltage according to the selected oscillation frequency and the estimated temperature change.

7. The semiconductor device according to claim 5, further comprising a temperature table storage unit configured to store a temperature table, the temperature table associating the control voltage at a temperature lower than the first temperature with the control voltage at a temperature higher than the first temperature, wherein the control voltage setting unit is configured to approximate the control voltage of each of the oscillation frequencies from the temperature table and set the control voltage according to the selected oscillation frequency and the estimated temperature change.

8. The semiconductor device according to claim 1, further comprising a control voltage generation circuit configured to supply the control voltage to the voltage control oscillation circuit in response to a setting signal, wherein the control voltage setting unit is configured to set the control voltage by switching the setting signal.

9. The semiconductor device according to claim 8, wherein the control voltage generation circuit comprises:
a voltage-dividing resistor configured to divide a power supply voltage; and
a switch configured to switch a voltage divided by the voltage-dividing resistor in response to the setting signal.

10. The semiconductor device according to claim 1, further comprising a counter configured to count the oscillation frequency, wherein
the oscillation frequency storage unit is configured to store a count value of the oscillation frequency at the first temperature, and
the control voltage setting unit is configured to set the control voltage based on a count value of the oscillation frequency at the second temperature and the stored count value.

11. The semiconductor device according to claim 1, wherein the calibration processing unit is configured to set the oscillation frequency to the voltage control oscillation circuit based on a difference between the oscillation frequency output from the voltage control oscillation circuit and a reference frequency.

12. The semiconductor device according to claim 11, further comprising a counter configured to count the oscillation frequency, wherein the calibration processing unit is configured to set the oscillation frequency to the voltage control oscillation circuit based on a difference between a count value of the oscillation frequency and a count value of the reference frequency.

13. The semiconductor device according to claim 12, wherein
the oscillation frequency of the voltage control oscillation circuit can be selected from among a plurality of oscillation frequencies, and
the calibration processing unit is configured to set the oscillation frequency to the voltage control oscillation circuit based on a difference between the oscillation frequency output from the voltage control oscillation circuit and the reference frequency corresponding to the selected oscillation frequency.

14. A radio communication apparatus comprising:
a PLL circuit comprising a voltage control oscillation circuit configured to control an oscillation frequency according to a control voltage;
an oscillation frequency storage unit configured to previously store the oscillation frequency at a first temperature;
a control voltage setting unit configured to set the control voltage based on a difference between the oscillation frequency at a second temperature and the stored oscillation frequency;
a calibration processing unit configured to calibrate the voltage control oscillation circuit in a state in which the control voltage is set so that the oscillation will become a predetermined frequency; and
a radio signal processing unit configured to process radio signals based on an oscillation frequency from the voltage control oscillation circuit that has been calibrated.

15. A control method for a semiconductor device comprising a PLL circuit including a voltage control oscillation circuit for controlling an oscillation frequency according to a control voltage, the control method comprising:
previously storing the oscillation frequency at a first temperature;
setting the control voltage based on a difference between the oscillation frequency at a second temperature and the stored oscillation frequency; and
calibrating the voltage control oscillation circuit in a state in which the control voltage is set so that the oscillation frequency will become a predetermined frequency.
